(19) United States
(12) Patent Application Publication
(10) Pub. No.: US 2026/0142649 A1
(43) Pub. Date: May 21, 2026

(54) SURFACE ACOUSTIC WAVE (SAW) FILTER HAVING TEMPERATURE COMPENSATION LAYER

(71) Applicant: WISOL CO., LTD., Gyeonggi-do (KR)

(72) Inventors: Toshihiko KAWAMOTO, Gyeonggi-do (KR); Min Sik Seol, Gyeonggi-do (KR); Ryota Sato, Gyeonggi-do (KR); Jae Kwan Ko, Gyeonggi-do (KR)

(21) Appl. No.: 19/385,703

(22) Filed: Nov. 11, 2025

(30) Foreign Application Priority Data
Nov. 18, 2024 (KR) 10-2024-0164058

(51) Int. Cl. H03H 9/64; H03H 9/02; H03H 9/25

(52) U.S. Cl. CPC H03H 9/6489; H03H 9/02834; H03H 9/25; H03H 9/6406; H03H 9/6483

(57) ABSTRACT

Disclosed is a surface acoustic wave (SAW) filter having a temperature compensation layer. The SAW filter includes: a series resonator group having a plurality of series-type SAW resonators connected in series; and a parallel resonator group having a plurality of parallel-type SAW resonators connected in parallel. Each of the series-type SAW resonators and the parallel-type SAW resonators comprises a piezoelectric substrate, an interdigital transducer (IDT) electrode formed on the piezoelectric substrate, and a temperature compensation layer covering the IDT electrode. At least one series-type SAW resonator among the series-type SAW resonators has a temperature compensation layer having a layer thickness different from layer thicknesses of temperature compensation layers of other series-type SAW resonators, or at least one parallel-type SAW resonator among the parallel-type SAW resonators has a temperature compensation layer having a layer thickness different from layer thicknesses of temperature compensation layers of other parallel-type SAW resonators.

### CROSS-REFERENCE TO RELATED APPLICATIONS

This application claims priority to Korean Patent Application No. 10-2024-0164058, filed on Nov. 18, 2024. The entire disclosure of the application identified in this paragraph is incorporated herein by reference.

### FIELD

The present disclosure relates to a surface acoustic wave (SAW) filter including surface acoustic wave resonators, and more particularly to a SAW filter having a temperature compensation layer.

### BACKGROUND

A surface acoustic wave (SAW) is an acoustic wave that propagates along the surface of an elastic substrate. These acoustic waves are generated from an electrical signal by the piezoelectric effect, and when the electric field associated with the acoustic waves is concentrated near the surface of the substrate, it may interact with conduction electrons of another semiconductor disposed directly above the surface. The medium through which the acoustic waves propagate is a piezoelectric material having a high electromechanical coupling coefficient and low acoustic wave energy loss. The semiconductor has high conduction electron mobility and optimal resistivity, and because the DC power requirement is low, optimal efficiency can be achieved. A surface acoustic wave (SAW) device is an electromechanical element that replaces an electronic circuit by utilizing the interaction between the surface acoustic waves and the conduction electrons of a semiconductor.

Such a surface acoustic wave device (hereinafter referred to as “SAW device”) is used not only in various communication applications but also as an essential component in mobile phones and base stations. The most commonly used SAW devices are passband filters and resonators. Because of the low cost, small size, and excellent technical characteristics (low loss and high selectivity), SAW devices have a substantially higher competitiveness than devices based on other physical principles.

Recently, there has been increasing interest in SAW filters for temperature compensation. However, in a SAW filter (TC SAW) for temperature compensation, the Q, k², and TCF of the resonator vary depending on the thickness of the SiO₂ that forms the temperature compensation layer. In general, in a TC SAW, since SiO₂ having the same thickness is applied to all resonators, the following problems arise.

In other words, in a SAW filter for temperature compensation, since the SiO₂ film thickness of the resonators are identical, there is a limitation in improving the Q value of a resonator intended to increase Q, and it is difficult to adjust k² for a resonator requiring a higher or lower value. In addition, it is difficult to minimize variations in the temperature coefficient of frequency (TCF).

### RELATED DOCUMENT

### Patent Document

(Patent Document 0001) Korean Patent No. 10-2015-0139856 (Published on 2015 Dec. 14.)

### SUMMARY

The present disclosure provides a surface acoustic wave (SAW) filter having a temperature compensation layer, which improves the Q value, k², and TCF by varying a layer thickness of the temperature compensation layer formed in resonators included in the SAW filter for temperature compensation.

In one general aspect of the present disclosure, a surface acoustic wave (SAW) filter having a temperature compensation layer includes: a series resonator group having a plurality of series-type SAW resonators connected in series; and a parallel resonator group having a plurality of parallel-type SAW resonators connected in parallel. Each of the series-type SAW resonators and the parallel-type SAW resonators comprises a piezoelectric substrate, an interdigital transducer (IDT) electrode formed on the piezoelectric substrate, and a temperature compensation layer covering the IDT electrode. At least one series-type SAW resonator among the series-type SAW resonators has a temperature compensation layer having a layer thickness different from layer thicknesses of temperature compensation layers of other series-type SAW resonators, or at least one parallel-type SAW resonator among the parallel-type SAW resonators has a temperature compensation layer having a layer thickness different from layer thicknesses of temperature compensation layers of other parallel-type SAW resonators.

The at least one series-type SAW resonator may correspond to a series-type SAW resonator having a smallest or a second smallest sum value of a resonance frequency and an anti-resonance frequency, and the series-type SAW resonator having the smallest or the second smallest sum value of the resonance frequency and the anti-resonance frequency may not have a thinnest temperature compensation layer among the series-type SAW resonators.

Among the temperature compensation layers of the series-type SAW resonators, a thickest temperature compensation layer has a layer thickness at least 1.03 times greater than a layer thickness of a thinnest temperature compensation layer.

The at least one parallel-type SAW resonator may correspond to a parallel-type SAW resonator having a largest or a second largest sum value of a resonance frequency and an anti-resonance frequency, and the parallel-type SAW resonator having the largest or the second largest sum value of the resonance frequency and the anti-resonance frequency may not have a thinnest temperature compensation layer among the parallel-type SAW resonators.

Among the temperature compensation layers of the parallel-type SAW resonators, a thickest temperature compensation layer may have a layer thickness at least 1.03 times greater than a layer thickness of a thinnest temperature compensation layer.

In yet another aspect, a surface acoustic wave (SAW) filter having a temperature compensation layer includes: a series resonator group having a plurality of series-type SAW resonators connected in series; and a parallel resonator group having a plurality of parallel-type SAW resonators connected in parallel. Each of the series-type SAW resonators and the parallel-type SAW resonators comprises a piezoelectric substrate, an interdigital transducer (IDT) electrode formed on the piezoelectric substrate, and a temperature compensation layer covering the IDT electrode. At least one series-type SAW resonator among the series-type SAW resonators has a temperature compensation layer having a layer thickness different from layer thicknesses of temperature compensation layers of other series-type SAW resonators, and at least one parallel-type SAW resonator among the parallel-type SAW resonators has a temperature compensation layer having a layer thickness different from thicknesses of temperature compensation layers of other parallel-type SAW resonators.

The at least one series-type SAW resonator may correspond to a series-type SAW resonator having a smallest or a second smallest sum value of a resonance frequency and an anti-resonance frequency, and the series-type SAW resonator having the smallest or the second smallest sum value of the resonance frequency and the anti-resonance frequency may not have a thinnest temperature compensation layer among the series-type SAW resonators.

Among the temperature compensation layers of the series-type SAW resonators, a thickest temperature compensation layer has a layer thickness at least 1.03 times greater than a layer thickness of a thinnest temperature compensation layer.

The at least one parallel-type SAW resonator may correspond to a parallel-type SAW resonator having a largest or a second largest sum value of a resonance frequency and an anti-resonance frequency, and the parallel-type SAW resonator having the largest or the second largest sum value of the resonance frequency and the anti-resonance frequency may not have a thinnest temperature compensation layer among the parallel-type SAW resonators.

Among the temperature compensation layers of the parallel-type SAW resonators, a thickest temperature compensation layer may have a layer thickness at least 1.03 times greater than a layer thickness of a thinnest temperature compensation layer.

### BRIEF DESCRIPTION OF THE DRAWINGS

FIG. 1 is a configuration diagram illustrating one embodiment of a surface acoustic wave (SAW) filter having a temperature compensation layer according to the present disclosure.

FIG. 2 is a cross-sectional view illustrating the structure of each resonator included in the SAW filter having the temperature compensation layer shown in FIG. 1.

FIG. 3 is a reference diagram illustrating the characteristics of series-type SAW resonators included in the SAW filter shown in FIG. 1.

FIG. 4 is a configuration diagram illustrating another embodiment of a SAW filter having a temperature compensation layer according to the present disclosure.

FIG. 5 is a reference diagram illustrating the characteristics of series-type SAW resonators included in the SAW filter shown in FIG. 4.

FIG. 6 is a configuration diagram illustrating yet another embodiment of a SAW filter having a temperature compensation layer according to the present disclosure.

### DETAILED DESCRIPTION

The terms used in this specification are intended to describe embodiments and are not intended to limit the present invention. In this specification, the singular forms also include the plural forms unless the context clearly indicates otherwise.

In this specification, the terms “include” or “have” and any variations thereof are intended to specify the presence of stated features, numbers, steps, operations, components, parts, or combinations thereof, but are not intended to preclude the presence or addition of one or more other features, numbers, steps, operations, components, parts, or combinations thereof. In addition, the embodiments described in this specification will be explained with reference to the cross-sectional and/or plan views, which are ideal examples of the present disclosure. Therefore, the embodiments of the present disclosure are not limited to the specific forms shown, but also include variations in form as needed. Therefore, the regions illustrated in the drawings have schematic properties, and the shapes of the regions illustrated in the drawings are intended to illustrate specific forms of regions of the device and are not intended to limit the scope of the present disclosure.

Hereinafter, a surface acoustic wave (SAW) filter having a temperature compensation layer according to the present disclosure will be explained with reference to the drawings.

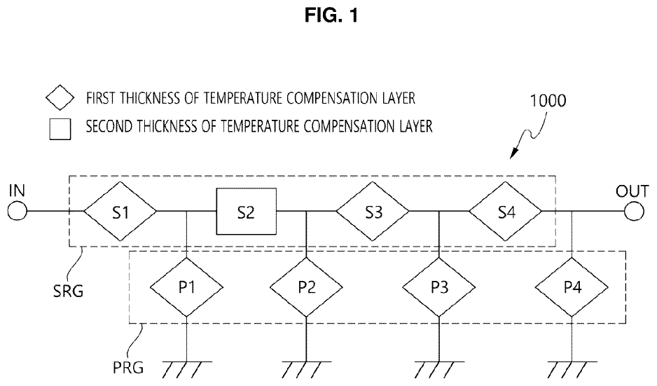

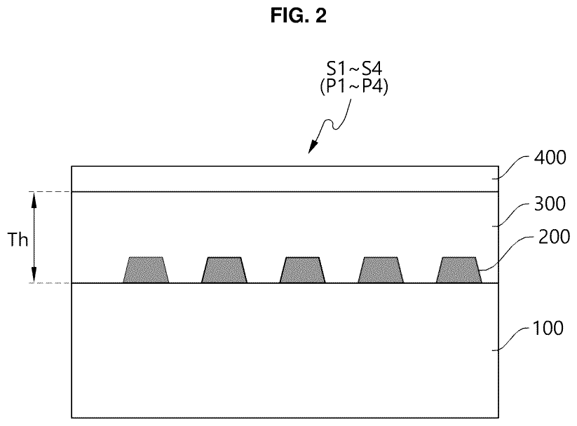

FIG. 1 is a schematic diagram of one embodiment to explain a SAW filter 1000 having a temperature compensation layer according to the present disclosure, and FIG. 2 is a cross-sectional view to explain the structure of each resonator that makes up the SAW filter 1000 having a temperature compensation layer shown in FIG. 1.

Referring to FIG. 1, the SAW filter 1000 with a temperature compensation layer includes a series resonator group SRG and a parallel resonator group PRG.

The series resonator group SRG includes a plurality of series-type SAW resonators S1, S2, S3, and S4 connected in series.

Referring to FIG. 2, each of the series-type SAW resonators S1, S2, S3, and S4 includes a piezoelectric substrate 100, an IDT electrode 200 formed on the piezoelectric substrate 100, a temperature compensation layer 300 covering the IDT electrode 200, and a protective layer 400 covering the temperature compensation layer 300.

The piezoelectric substrate 100 is formed of a material capable of providing a piezoelectric effect. For example, the piezoelectric substrate 100 may be one of a silicon substrate, a diamond substrate, a sapphire substrate, a silicon carbide substrate, a LiNbO₃ substrate, or a LiTaO₃ substrate.

A plurality of IDT electrodes 200 may be alternately arranged at regular intervals. One group of the IDT electrodes 200 may serve as an input electrode, and the other group may serve as an output electrode.

The temperature compensation layer 300 is a layer for stabilizing the temperature characteristics of a surface acoustic wave device. For example, the temperature compensation layer 300 may be formed of silicon oxide (SiO₂).

The temperature compensation layers 300 of the resonators included in the series resonator group SRG and the parallel resonator group PRG generally have the same layer thickness. However, in the present disclosure, the temperature compensation layers 300 forming the series resonator group SRG or the parallel resonator group PRG may be configured to have different layer thickness Th.

The protective layer 400 is a layer for protecting a surface acoustic wave device. For example, the protective layer 400 may be formed of silicon nitride (SIN).

However, the protective layer 400 may not cover the temperature compensation layer 300, or may cover only a part of the temperature compensation layer 300, depending on the purpose of the present disclosure. Like the temperature compensation layer 300 described above, the layer thickness of the protective layer 400 may also differ between the series resonator group SRG and the parallel resonator group PRG.

In FIG. 1, the series resonator group SRG includes a plurality of series-type SAW resonators S1, S2, S3, and S4 connected in series.

Among the series-type SAW resonators S1, S2, S3, and S4 in the series resonator group SRG, at least one series-type SAW resonator may have a temperature compensation layer having a layer thickness different from those of the temperature compensation layers of the other series-type SAW resonators.

In other words, the temperature compensation layer of at least one series-type SAW resonator (for example, the series-type SAW resonator S2) among the series-type SAW resonators S1, S2, S3, and S4 may have a layer thickness different from those of the temperature compensation layers of the other series-type SAW resonators S1, S3, and S4.

In this case, at least one series-type SAW resonator S2 may correspond to a resonator having the smallest or the second smallest sum value of a resonance frequency and an anti-resonance frequency.

The series-type SAW resonator S2 having the smallest or second smallest sum value of the resonance frequency and the anti-resonance frequency may not have a thinnest temperature compensation layer among the series-type SAW resonators S1, S3, and S4.

At least one series-type SAW resonator S2 having a layer thickness different from those of the temperature compensation layers of the other series-type SAW resonators S1, S3, and S4 corresponds to a series-type SAW resonator having a smallest or a second smallest sum value Fr+Fa of a resonance frequency Fr and an anti-resonance frequency Fa.

In this case, the temperature compensation layer of the series-type SAW resonator S2 having the smallest or the second smallest sum value Fr+Fa may have a layer thickness relatively greater than those of the temperature compensation layers of the series-type SAW resonators S1, S3, and S4.

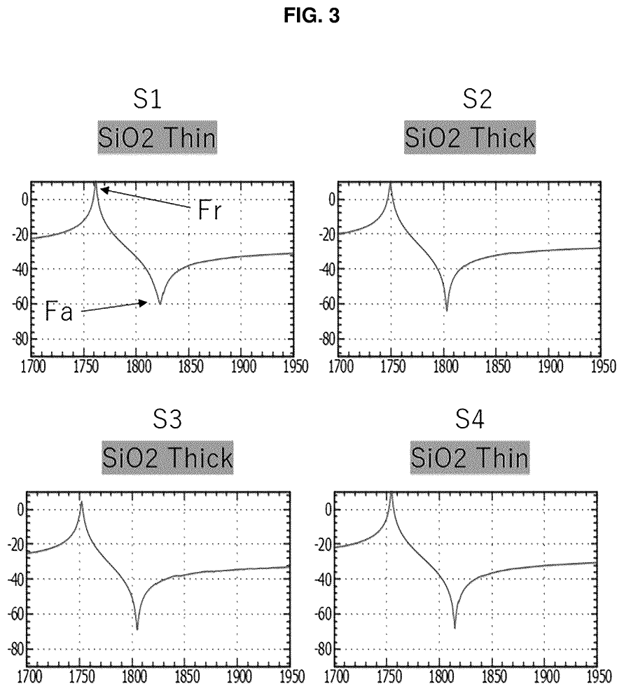

FIG. 3 is a reference diagram illustrating the characteristics of the series-type SAW resonators S1, S2, S3, and S4 included in the SAW filter 1000 shown in FIG. 1.

FIG. 3 shows resonance frequencies Fr and anti-resonance frequencies Fa of the series-type SAW resonators S1, S2, S3, and S4 in the series resonator group SRG.

The positions of the resonance frequency Fr and the anti-resonance frequency Fa vary depending on the layer thickness of the temperature compensation layer of each of the series-type SAW resonators S1, S2, S3, and S4.

The characteristics of the layer thicknesses, the resonance frequencies Fr, and anti-resonance frequencies Fa of the series-type SAW resonators S1, S2, S3, and S4 shown in FIG. 3 are summarized in Table 1 below.

TABLE 1

| | Thickness of | | Anti- | | |
|---|---|---|---|---|---|
| | Temperature | Resonance | Resonance | | |
| | Compensation | Frequency | Frequency | | Rank of |
| | Layer | (Fr) | (Fa) | Fr + Fa | Fr + Fa |
| S1 | Thin | 1762 | 1823 | 3585 | 1 |
| S2 | Thick | 1750 | 1803 | 3553 | 4 |
| S3 | Thick | 1753 | 1805 | 3558 | 3 |
| S4 | Thin | 1754 | 1814 | 3568 | 2 |

In Table 1, among the series-type SAW resonators S1, S2, S3, and S4 in the series resonator group SRG, the series-type SAW resonator S2 has the smallest sum value Fr+Fa of the resonance frequency Fr and the anti-resonance frequency Fa. Accordingly, the temperature compensation layer of the series-type SAW resonator S2, which has the smallest sum value Fr+Fa, may have a layer thickness relatively greater than those of the temperature compensation layers of the other series-type SAW resonators S1, S3, and S4.

In addition, even when the temperature compensation layers of the series-type SAW resonators in the series resonator group SRG have three or more different layer thicknesses, the series-type SAW resonator having the smallest or the second smallest sum value Fr+Fa does not have a thinnest temperature compensation layer among the series-type SAW resonators in the series resonator group SRG. In other words, the temperature compensation layer of the series-type SAW resonator having the smallest or the second smallest sum value Fr+Fa may have a relatively greater layer thickness compared to the temperature compensation layers of the other series-type SAW resonators.

Meanwhile, among the temperature compensation layers of the series-type SAW resonators, a layer thickness of the temperature compensation layer having the greatest layer thickness may be at least 1.03 times greater than a layer thickness of the thinnest temperature compensation layer.

For example, when the temperature compensation layers have two or more different layer thicknesses, the difference in layer thickness between the series-type SAW resonator having a thickest temperature compensation layer and the series-type SAW resonator having a thinnest temperature compensation layer may be 1.03 times or greater. This relationship may be expressed by the following Equation 1:

$$T {h}_{S 1} \geq T {h}_{S} * 1.03 \qquad [ Equation l ]$$

In Equation 1, Th_{S1} denotes the layer thickness of the series-type SAW resonator having the thickest temperature compensation layer, and Th_{S2} denotes the layer thickness of the series-type SAW resonator having a thinnest temperature compensation layer.

The parallel resonator group PRG includes a plurality of parallel-type SAW resonators P1, P2, P3, and P4 connected in parallel.

Referring to FIG. 2, similarly to the series-type SAW resonators S1, S2, S3, and S4, each of the parallel-type SAW resonators P1, P2, P3, and P4 includes a piezoelectric substrate 100, an IDT electrode 200 formed on the piezoelectric substrate 100, a temperature compensation layer 300 covering the IDT electrode 200, and a protective layer 400 covering the temperature compensation layer 300.

However, in the case of the parallel resonator group PRG, the temperature compensation layers 300 of the parallel-type SAW resonators P1, P2, P3, and P4 have the same layer thickness, unlike those of the series-type SAW resonators S1, S2, S3, and S4.

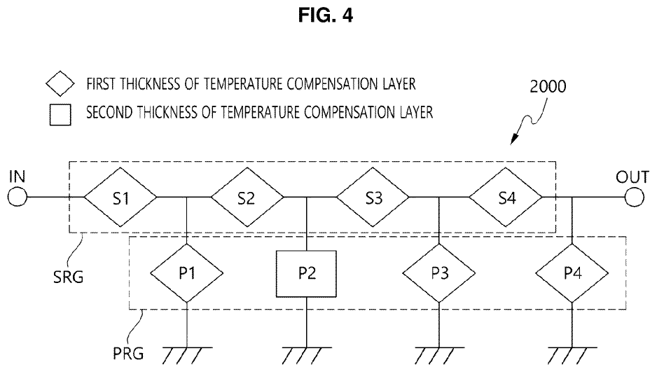

FIG. 4 is a schematic diagram of another embodiment to illustrate a SAW filter 2000 having a temperature compensation layer according to the present disclosure.

Referring to FIG. 4, the SAW filter 2000 of another embodiment includes a series resonator group SRG and a parallel resonator group PRG.

The series resonator group SRG includes a plurality of series-type SAW resonators S1, S2, S3, and S4.

As shown in FIG. 2, each of the series-type SAW resonators S1, S2, S3, and S4 includes a piezoelectric substrate 100, an IDT electrode 200 formed on the piezoelectric substrate 100, a temperature compensation layer 300 covering the IDT electrode 200, and a protective layer 400 covering the temperature compensation layer 300.

In this case, the temperature compensation layers 300 of the series-type SAW resonators S1, S2, S3, and S4 have the same layer thickness.

The parallel resonator group PRG includes a plurality of parallel-type SAW resonators P1, P2, P3, and P4 connected in parallel.

Similarly, each of the parallel-type SAW resonators P1, P2, P3, and P4 includes a piezoelectric substrate 100, an IDT electrode 200 formed on the piezoelectric substrate 100, a temperature compensation layer 300 covering the IDT electrode 200, and a protective layer 400 covering the temperature compensation layer 300.

The temperature compensation layer of at least one of the parallel-type SAW resonators P1, P2, P3, and P4 in the parallel resonator group PRG has a different layer thickness from those of the other parallel-type SAW resonators.

In other words, the temperature compensation layer of the at least one parallel-type SAW resonator P2 has a different layer thickness from those of the other parallel-type SAW resonators P1, P3, and P4.

In this case, the at least one parallel-type SAW resonator P2 may correspond to a parallel-type SAW resonator having the largest or the second largest sum value of a resonance frequency Fr and an anti-resonance frequency Fa.

The parallel-type SAW resonator P2 having the largest or the second largest sum value Fr+Fa may not have a thinnest temperature compensation layer among the parallel-type SAW resonators.

At least one parallel-type SAW resonator P2 having a layer thickness different from those of the other parallel-type SAW resonators P1, P3, and P4 corresponds to a parallel-type SAW resonator having the largest or the second largest sum value Fr+Fa.

In this case, the temperature compensation layer of the parallel-type SAW resonator P2 having the largest or the second largest sum value Fr+Fa may have a layer thickness relatively greater than those of the temperature compensation layers of the other parallel-type SAW resonators P1, P3, and P4.

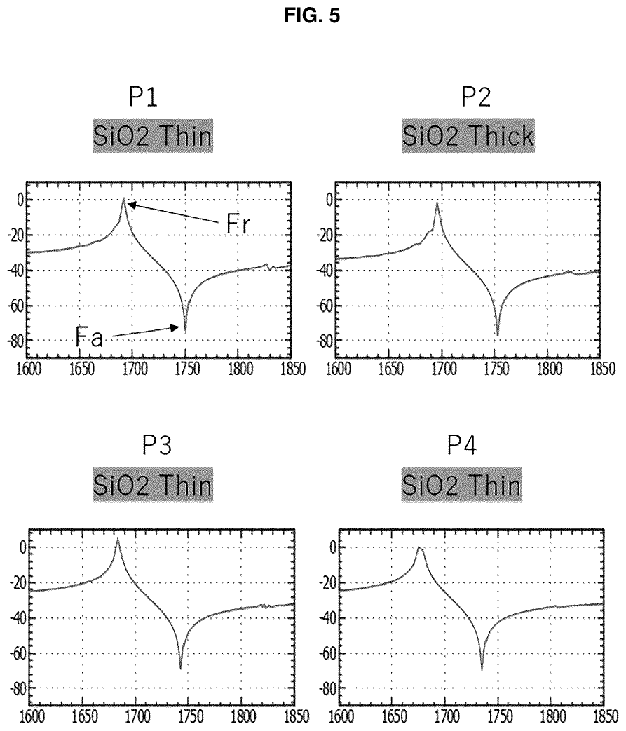

FIG. 5 is a reference diagram illustrating the characteristics of the parallel-type SAW resonators P1, P2, P3, and P4 of the SAW filter 2000 shown in FIG. 4.

According to FIG. 5, the resonance frequency Fr and the anti-resonance frequency Fa of the parallel-type SAW resonators P1, P2, P3, and P4 in the parallel resonator group PRG are shown. The positions of the resonance frequency Fr and the anti-resonance frequency Fa vary depending on the layer thickness of the temperature compensation layer of each of the parallel-type SAW resonators P1, P2, P3, and P4.

The characteristics of the layer thicknesses, the resonance frequencies Fr, and anti-resonance frequencies Fa of the parallel-type SAW resonators P1, P2, P3, and P4 shown in FIG. 5 are summarized in Table 2 below.

TABLE 2

| | Thickness of | | Anti- | | |
|---|---|---|---|---|---|
| | Temperature | Resonance | Resonance | | |
| | Compensation | Frequency | Frequency | | Rank of |
| | Layer | (Fr) | (Fa) | Fr + Fa | Fr + Fa |
| P1 | Thin | 1691 | 1750 | 3441 | 2 |
| P2 | Thick | 1695 | 1753 | 3448 | 1 |
| P3 | Thin | 1682 | 1743 | 3425 | 3 |
| P4 | Thin | 1675 | 1736 | 3411 | 4 |

In Table 2, among the parallel-type SAW resonators P1, P2, P3, and P4 in the parallel resonator group PRG, the parallel-type SAW resonator P2 has the largest sum value Fr+Fa of the resonance frequency Fr and the anti-resonance frequency Fa, compared to the other parallel-type SAW resonators P1, P3, and P4. Accordingly, the temperature compensation layer 300 of the parallel-type SAW resonator P2 having the largest sum value Fr+Fa may have a layer thickness relatively greater than those of the temperature compensation layers 300 of the other parallel-type SAW resonators P1, P3, and P4. In addition, even when the temperature compensation layers 300 of the parallel-type SAW resonators in the parallel resonator group PRG have three or more different layer thicknesses, the parallel-type SAW resonator having the largest or the second largest sum value Fr+Fa does not have a thinnest temperature compensation layer among the parallel-type SAW resonators in the parallel resonator group PRG. In other words, the temperature compensation layer of the parallel-type SAW resonator having the largest or the second largest sum value Fr+Fa may have a relatively greater layer thickness than those of the temperature compensation layers of the other parallel-type SAW resonators.

Meanwhile, among the temperature compensation layers of the parallel-type SAW resonators, a layer thickness of the thickest temperature compensation layer may be at least 1.03 times greater than a layer thickness of the thinnest temperature compensation layer.

For example, when the temperature compensation layers have two or more different layer thicknesses, the difference in layer thickness between the parallel-type SAW resonator having a thickest temperature compensation layer and the parallel-type SAW resonator having a thinnest temperature compensation layer may be 1.03 times or greater. This relationship may be expressed by the following Equation 2:

$$T {h}_{P 1} \geq T {h}_{P {2}^{}} * 1.03 \qquad [ Equation 2 ]$$

In Equation 2, Th_{P1} denotes the layer thickness of the parallel-type SAW resonator having the thickest temperature compensation layer, and Th_{P2} denotes the layer thickness of the parallel-type SAW resonator having a thinnest temperature compensation layer.

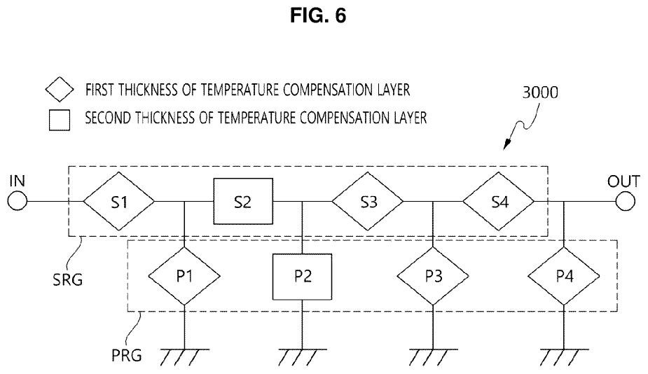

FIG. 6 is a schematic diagram illustrating another embodiment 3000 of a SAW filter having a temperature compensation layer according to the present disclosure.

Referring to FIG. 6, the SAW filter 3000 of another embodiment includes a series resonator group SRG and a parallel resonator group PRG.

The series resonator group SRG includes a plurality of series-type SAW resonators S1, S2, S3, and S4. As shown in FIG. 2, each of the series-type SAW resonators S1, S2, S3, and S4 includes a piezoelectric substrate 100, an IDT electrode 200 formed on the piezoelectric substrate 100, a temperature compensation layer 300 covering the IDT electrode 200, and a protective layer 400 covering the temperature compensation layer 300.

At least one of the series-type SAW resonators S1, S2, S3, and S4 in the series resonator group SRG has a temperature compensation layer 300 having a layer thickness different from those of the temperature compensation layers of the other series-type SAW resonators. In this case, at least one series-type SAW resonator S2 among the series-type SAW resonators S1, S2, S3, and S4 may correspond to a series-type SAW resonator having the smallest or the second smallest sum value Fr+Fa of the resonance frequency Fr and the anti-resonance frequency Fa. The layer thickness characteristics of the series-type SAW resonators S1, S2, S3, and S4 according to the sum value of frequencies are the same as those illustrated in FIGS. 1 and 3, and thus a detailed description thereof will be omitted.

Among the temperature compensation layers 300 of the series-type SAW resonators, a layer thickness of the thickest temperature compensation layer may be at least 1.03 times greater than a layer thickness of the thinnest temperature compensation layer. For example, when the temperature compensation layers 300 have two or more different layer thicknesses, the difference in thickness between the series-type SAW resonator having a thickest temperature compensation layer and the series-type SAW resonator having a thinnest temperature compensation layer may be 1.03 times or greater.

In addition, at least one of the parallel-type SAW resonators P1, P2, P3, and P4 in the parallel resonator group PRG has a temperature compensation layer 300 having a layer thickness different from those of the temperature compensation layers of the other parallel-type SAW resonators. In this case, at least one parallel-type SAW resonator P2 may correspond to the parallel-type SAW resonator having the largest or the second largest sum value Fr+Fa. The layer thickness characteristics of the parallel-type SAW resonators P1, P2, P3, and P4 according to the sum value of frequencies are the same as those illustrated in FIGS. 4 and 5, and thus a detailed description thereof will be omitted.

Among the temperature compensation layers 300 of the parallel-type SAW resonators, the layer thickness of the thickest temperature compensation layer may be at least 1.03 times greater than the thinnest temperature compensation layer. For example, when the temperature compensation layers 300 have two or more different layer thicknesses, the difference in layer thickness between the parallel-type SAW resonator having the thickest temperature compensation layer and the parallel-type SAW resonator having the thinnest temperature compensation layer may be 1.03 times or greater.

According to the present disclosure, it is possible to improve the Q value and TCF and to adjust k² by varying the layer thicknesses of the temperature compensation layers between the series-type SAW resonators that produce a high-skirt main characteristic and the parallel-type SAW resonators that produce a low-skirt main characteristic.

Accordingly, in the SAW filter for temperature compensation, an excellent TCF enables steep skirt characteristics to be realized by reducing k², insertion loss is improved through enhancement of the Q value, and broadband pass characteristics may be improved through the increase of k².

Although the technical concept of the present disclosure has been described above with reference to the accompanying drawings, this description is merely illustrative of exemplary embodiments of the present disclosure and is not intended to limit the scope thereof.

Therefore, the present disclosure is not limited to the specific embodiments described above. Various modifications, alterations, and equivalent arrangements may be made by those skilled in the art without departing from the spirit or scope of the invention as defined by the appended claims, and all such changes shall fall within the scope of the claims.

What is claimed is:

1. A surface acoustic wave (SAW) filter having a temperature compensation layer, comprising:
a series resonator group having a plurality of series-type SAW resonators connected in series; and
a parallel resonator group having a plurality of parallel-type SAW resonators connected in parallel,
wherein each of the series-type SAW resonators and the parallel-type SAW resonators comprises a piezoelectric substrate, an interdigital transducer (IDT) electrode formed on the piezoelectric substrate, and a temperature compensation layer covering the IDT electrode, and
wherein at least one series-type SAW resonator among the series-type SAW resonators has a temperature compensation layer having a layer thickness different from layer thicknesses of temperature compensation layers of other series-type SAW resonators, or at least one parallel-type SAW resonator among the parallel-type SAW resonators has a temperature compensation layer having a layer thickness different from layer thicknesses of temperature compensation layers of other parallel-type SAW resonators.

2. The SAW filter of claim 1, wherein:
the at least one series-type SAW resonator corresponds to a series-type SAW resonator having a smallest or a second smallest sum value of a resonance frequency and an anti-resonance frequency, and
the series-type SAW resonator having the smallest or the second smallest sum value of the resonance frequency and the anti-resonance frequency does not have a thinnest temperature compensation layer among the series-type SAW resonators.

3. The SAW filter of claim 1, wherein, among the temperature compensation layers of the series-type SAW resonators, a thickest temperature compensation layer has a layer thickness at least 1.03 times greater than a layer thickness of a thinnest temperature compensation layer.

4. The SAW filter of claim 1, wherein:
the at least one parallel-type SAW resonator corresponds to a parallel-type SAW resonator having a largest or a second largest sum value of a resonance frequency and an anti-resonance frequency, and
the parallel-type SAW resonator having the largest or the second largest sum value of the resonance frequency and the anti-resonance frequency does not have a thinnest temperature compensation layer among the parallel-type SAW resonators.

5. The SAW filter of claim 1, wherein, among the temperature compensation layers of the parallel-type SAW resonators, a thickest temperature compensation layer has a layer thickness at least 1.03 times greater than a layer thickness of a thinnest temperature compensation layer.

6. A surface acoustic wave (SAW) filter having a temperature compensation layer, comprising:
a series resonator group having a plurality of series-type SAW resonators connected in series; and
a parallel resonator group having a plurality of parallel-type SAW resonators connected in parallel,
wherein each of the series-type SAW resonators and the parallel-type SAW resonators comprises a piezoelectric substrate, an interdigital transducer (IDT) electrode formed on the piezoelectric substrate, and a temperature compensation layer covering the IDT electrode, and
wherein at least one series-type SAW resonator among the series-type SAW resonators has a temperature compensation layer having a layer thickness different from layer thicknesses of temperature compensation layers of other series-type SAW resonators, and at least one parallel-type SAW resonator among the parallel-type SAW resonators has a temperature compensation layer having a layer thickness different from thicknesses of temperature compensation layers of other parallel-type SAW resonators.

7. The SAW filter of claim 6, wherein:
the at least one series-type SAW resonator corresponds to a series-type SAW resonator having a smallest or a second smallest sum value of a resonance frequency and an anti-resonance frequency, and
the series-type SAW resonator having the smallest or the second smallest sum value of the resonance frequency and the anti-resonance frequency does not have a thinnest temperature compensation layer among the series-type SAW resonators.

8. The SAW filter of claim 6, wherein, among the temperature compensation layers of the series-type SAW resonators, a thickest temperature compensation layer has a layer thickness at least 1.03 times greater than a layer thickness of a thinnest temperature compensation layer.

9. The SAW filter of claim 6, wherein:
at least one parallel-type SAW resonator corresponds to a parallel-type SAW resonator having a largest or a second largest sum value of a resonance frequency and an anti-resonance frequency, and
the parallel-type SAW resonator having the largest or the second largest sum value of the resonance frequency and the anti-resonance frequency does not have a thinnest temperature compensation layer among the parallel-type SAW resonators.

10. The SAW filter of claim 6, wherein, among the temperature compensation layers of the parallel-type SAW resonators, a thickest temperature compensation layer has a layer thickness at least 1.03 times greater than a layer thickness of a thinnest temperature compensation layer.
